(19) United States
(12) Patent Application Publication
(10) Pub. No.: US 2016/0245843 A1
(43) Pub. Date: Aug. 25, 2016

(54) SCANNING PROBE MICROSCOPE PROBER EMPLOYING SELF-SENSING CANTILEVER

(71) Applicant: WAFER INTEGRATION INC., Ibaraki (JP)

(72) Inventors: Ryu SHIODA, Tsukuba-shi (JP); Yoshiyuki AMANO, Tsukuba-shi (JP)

(73) Assignee: WAFER INTEGRATION INC., Tsukuba-shi, Ibaraki (JP)

(21) Appl. No.: 14/898,850

(22) PCT Filed: Nov. 1, 2013
(86) PCT No.: PCT/JP2013/080364

§ 371 Date: Mar. 24, 2016

(30) Foreign Application Priority Data
Jul. 16, 2013 (JP) 2013-147752

(51) Int. Cl. G01Q 60/38; G01R 19/00

(52) U.S. Cl. CPC G01Q 60/38; G01R 19/00

(57) ABSTRACT

A scanning probe microscope prober employs a self-sensing cantilever including a first wire through which a current is supplied to a probe, and a second wire used in a sensor circuit for detecting a deformation of the cantilever. The prober includes guard potential generation means for causing the second wire to be employed as a guard wire for the first wire, and second wire switching means for switching over the second wire to be used in a time division manner in one of a first period during which the second wire is used as a sensor, and a second period during which the second wire is held at a guard potential. The probe is moved, after obtaining a two-dimensional distribution in the first period, to a predetermined position on the basis of the two-dimensional distribution in the second period for measuring a current or voltage of the first wire.

### TECHNICAL FIELD

The present invention relates to a scanning probe microscope prober using a self-sensing cantilever, which can perform electrical measurements while a probe is directly contacted with a microscopic region in a highly integrated semiconductor device where observation using an optical microscope is difficult to carry out.

### BACKGROUND ART

Electrical measurements using a nanoprober of multiprobe AFM (atomic force microscope) is widely used in failure analyses of semiconductor devices that are produced with manufacturing processes at a hyperfine rule level. Before a transistor is operated for an ordinary DC (direct current) measurement, a device failure, such as a leak from an electrode, is often found by capturing an image of a current, which flows through a backside earth terminal, another electrode, or the like, under the operation of an AFM for narrowing down a defect position. However, the number of devices in which a current is difficult to take out from the backside, such as an SOI (silicon-on-insulator) substrate, increases. Furthermore, when wafer measurements are performed inline, it is difficult in not a few cases to take out a current signal from the backside depending on process situations. In those cases, an image of a current is captured with respect to a predetermined electrode.

Nanoprobers for ranges where measurement objects cannot be observed by an optical microscope are divided into that probing is performed under observation with an SEM (scan electron microscope), and that probing is performed while an image is captured by a probe of the AFM itself. When failure analyses of highly integrated semiconductor devices are performed by employing the nanoprobers, it is thought that the AFM nanoprober is advantageous for most advanced devices, which are miniaturized in accordance with an exposure rule of sub-microns or less, for example. This is because using the SEM raises problems, e.g., degradation of device characteristics attributable to damages caused by an electron beam, and formation of an insulating layer by the remaining hydrocarbons.

An AFM probe usually used is movable in itself. In general, four to six AFM probes are used in a state where each probe is fixed to a cantilever, and the individual probes are movable in XYZ directions at resolution of nanometer (nm) independently of one another. The probes are each moved with driving of a piezoelectric element through the cantilever. The usually used probe includes a tip with a radius of several nanometers (for advanced devices), and the tip can be directly contacted with an electrode. Moreover, all mechanisms necessary for the AFM are usually disposed within an angle of 60° or less relative to the tip.

As related art, for example, Patent Literature (Patent Reference) 1 (Specification of U.S. Pat. No. 6,668,628 B2) discloses scanning probe devices, e.g., an SPM (scanning probe microscope) and an AFM (atomic force microscope), and further states a concept of fabricating a plurality of probes into an integral unit, which has a predetermined structure, through semiconductor processes and so on. However, a distance between microscopic electrodes in an advanced semiconductor device is reduced down to 100 nm or less, and it is practically almost impossible to fabricate a structure including the plurality of probes that are positioned close to each other at such a distance level. Furthermore, because the probe tip is worn with scanning of the AFM, the probe needs to be replaced frequently, and the probe is demanded to be manufactured at a lower cost.

When failure analyses of microscopic semiconductor devices are performed as described above, individual probes needs to be contacted with predetermined locations, respectively. On that occasion, position control of each probe needs to be performed in units of several tens nanometers, and the position control is very difficult to perform under observation with an optical microscope. For that reason, the position control of the probe is performed with the aid of images captured by the SEM (scanning electron microscope) or the AFM (atomic force microscope).

FIG. 2 illustrates, as a practical example, an operating screen for probing to perform electrical measurements with a nanoprober of related art. In this example, the probing is carried out by recognizing, from four AFM images obtained in an arrangement of FIG. 2(a), an electrode with which a probe is to be contacted. More specifically, the scanning is stopped from a state of surface observation under application of a force at an nN level in AFM imaging, and the probe is pressed against the specified electrode with a force of several hundred nN. However, it is difficult to obtain the objective contact by one operation because the positional relation between the probe and the electrode during the scanning is changed due to, e.g., temperature change and creep of a piezoelectric drive element. To cope with such a difficulty, control is usually executed in a mode of the so-called closed loop. In the closed loop control, for example, electrostatic capacitance is monitored by a position sensor, and a deviation caused due to, e.g., creep of a piezoelectric drive system, is evaluated in terms of an absolute value for feedback control. However, it often happens that, with a deviation of several nanometers, electrical conduction (contact) is changed and a contact resistance is increased. The contact can be checked, for example, by monitoring a current that flows from the probe to the backside of a sample through a device electrode, and by obtaining a current-voltage characteristic. Adjustment of a degree of the contact in this stage is usually performed by changing a pressure applied to the probe, or by moving a position of the probe. In fact, however, the probe is at a position away through a distance of about 1 μm or more, for example, and control in an nm order is needed to move the probe to the objective predetermined electrode. Such a movement is sometimes performed on the basis of an AFM image of the probe itself as mentioned above, but an operation of performing such a movement with the AFM image is also fairly difficult.

In trying to establish the contact, it is important, in the example of FIG. 2, to determine relative positions of the probes from the four AFM images, and to perform control in a way of avoiding the probes from crossing each other. In a contact state, the probe is pressed against the electrode (conductive plug 18 in the example of FIG. 2) with a force stronger than that applied during the scanning by about double digits without feeding back a force. In that case, the contact can be obtained with a force of about hundreds of nN, including a flexure of the cantilever. The force at such a level is weaker than that applied in the SEM nanoprober, and damage of the probe tip is less likely to occur.

FIG. 1 illustrates an example of a multi-probe AFM nanoprober of related art. This example includes a plurality of probes as in the above-mentioned case, and scans a predetermined portion of an inspection object by moving the probes.

Furthermore, Patent Reference 2 (Specification of U.S. Pat. No. 6,880,389 B2), for example, discloses a method of carrying out scanning in a very small region by employing a plurality of scanning probes that are mounted to AFM cantilevers, and an SPM device for implementing the method. This SPM device includes a controller for controlling the probes in a manner of avoiding collision between the probes when the scanning is performed on regions partly overlapping with each other. Patent Reference 3 (Specification of U.S. Pat. No. 6,951,130 B2) also discloses a method of carrying out scanning in a very small region by employing a plurality of scanning probes that are mounted to AFM cantilevers, and an SPM device for implementing the method. This SPM device includes a controller for, when the probes are going to cross each other in an operation of moving the probes to scan a predetermined region, executing control to retract one of the probes from the predetermined region in a manner of avoiding collision between the probes. Patent Reference 4 (Specification of U.S. Pat. No. 7,444,857 B2) discloses an SPM device for carrying out scanning with a plurality of scanning probes that are mounted to AFM cantilevers having respective specific coordinate systems, and a method for controlling the probes. According to this related art, the scanning is performed while the probes are maintained in offset states in the respective coordinate systems such that the probes will not interfere with each other.

### RELATED ART REFERENCE

### Patent References

Patent Reference 1: Specification of U.S. Pat. No. 6,668,628
Patent Reference 2: Specification of U.S. Pat. No. 6,880,389
Patent Reference 3: Specification of U.S. Pat. No. 6,951,130
Patent Reference 4: Specification of U.S. Pat. No. 7,444,857
Patent Reference 5: Japanese Unexamined Patent Application Publication No. 6-300557

### SUMMARY OF THE INVENTION

### Problems to be Solved by the Invention

In a scanning probe microscope prober using a self-sensing cantilever, a microscopic region of a measurement object is measured by obtaining an SPM (scanning probe microscope) image of the microscopic region and thereabout, and by contacting a probe with the microscopic region with the aid of the image. To measure a minute current at a level of pA or less, a sensor circuit for detecting a deformation of a cantilever is employed to provide a guard electrode with the cantilever.

### Means for Solving the Problems

The present invention provides a scanning probe microscope prober using a self-sensing cantilever capable of performing electrical measurements of a measurement object placed on a two-dimensionally scanned sample stage by employing a probe mounted on a two-dimensionally scanned probe stage, and capable of obtaining a two-dimensional distribution of a control variable used to hold a force acting on the probe or a current flowing through the probe at a predetermined value,

the prober comprising setting means for setting the probe to a position determined on basis of the two-dimensional distribution of the control variable, and measurement means for measuring a current or a voltage between the probe and a predetermined location of the measurement object,

wherein the probe is disposed at a distal end of a cantilever,

the cantilever is self-sensing cantilever,

the self-sensing cantilever includes a first wire through which the current is supplied to the probe, and a second wire used in a sensor circuit for detecting a deformation of the cantilever, and

the prober further comprises:

detection means for detecting change in an output of the sensor circuit;

guard potential generation means for causing the second wire to be employed as a guard wire for the first wire; and

second wire switching means for switching over the second wire to be used in a time division manner in one of a first period during which the second wire is used as a sensor, and a second period during which the second wire is held at a guard potential, and

wherein the probe moves, after obtaining the two-dimensional distribution in the first period, to a predetermined position on basis of the two-dimensional distribution in the second period to measure a current or a voltage of the first wire.

The two-dimensional distribution of the control variable is obtained by scanning the sample stage.

An operation of moving the probe to a predetermined position on the basis of the two-dimensional distribution in the second period is performed by moving the probe stage.

Each of the sample stage and the probe stage includes a linear encoder for detecting displacements of the stage in three-dimensional directions, and a drive system for driving the stage in the three-dimensional directions,

the prober includes closed loop control systems each controlling the corresponding stage to be held at a predetermined position of the linear encoder by employing the linear encoder and the drive system, and

closed loop control is executed in at least one of the closed loop control systems in the second period.

The scanning probe microscope prober using the self-sensing cantilever, according to the present invention, further includes determination means for determining whether a voltage-current characteristic is within a predetermined range with respect to a measured value of the current or the voltage of the first wire,

wherein the measurement is performed through the steps of:

(1) determining the voltage-current characteristic by the determination means when the current or the voltage is measured,

(2) when the voltage-current characteristic is within the predetermined range, outputting the measured current or voltage, and

(3) when the voltage-current characteristic is not within the predetermined range, obtaining the two-dimensional distribution of the control variable again, moving the probe to a predetermined position on basis of the two-dimensional distribution obtained again by moving the probe stage, and thereafter returning to the first step (1) for measuring.

The scanning probe microscope type prober using the self-sensing cantilever further includes

coordinate conversion means for determining, for a predetermined position of an identical measurement object, conversion coefficients between coordinate values indicated by a linear encoder of the sample stage and coordinate values indicated by a linear encoder of the probe stage from comparison between a two-dimensional distribution A obtained with driving of the sample stage and a two-dimensional distribution B obtained with driving of the probe stage, and executing coordinate conversion by employing the conversion coefficients,

wherein an operation of moving the probe to the predetermined position on basis of the two-dimensional distribution in the second period is performed by employing values for movement obtained through conversion with the coordinate conversion means.

### Effect of the Invention

In electrical measurements using a multi-probe nanoprober, which are necessary in failure analyses of semiconductor devices produced with manufacturing processes at a hyperfine rule level, probe setting-up that is difficult to perform with the use of an optical microscope can be performed in an easier manner and in a state generating a smaller leak current.

### BRIEF DESCRIPTION OF THE DRAWINGS

FIG. 1 illustrates an example of a multi-probe AFM nanoprober of related art.

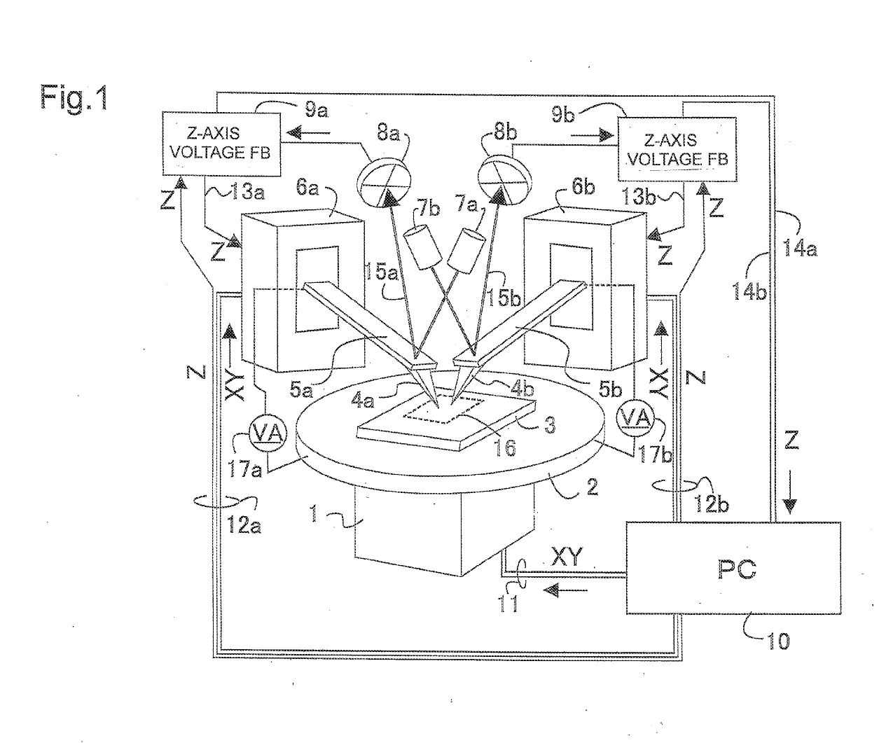

FIG. 2 illustrates an example of the case of contacting probes with plug-shaped electrodes; specifically, FIG. 2(a) is a plan view, and FIG. 2(b) is a side view.

FIG. 3 is a schematic view of a scanning probe microscope prober using a self-sensing cantilever according to the present invention.

FIG. 4 is a schematic view illustrating a structural example of a cantilever.

FIG. 5 is a block diagram of the scanning probe microscope prober using the self-sensing cantilever according to the present invention.

FIG. 6 illustrates the procedures for electrical measurements of a measurement object 3 by the scanning probe microscope prober using the self-sensing cantilever according to the present invention.

FIG. 7(a) illustrates two maps obtained as AFM images and including an overlapped portion, and FIG. 7(b) illustrates a map resulting from combining those two maps with each other.

FIG. 8 is an illustration representing a relation between a drive shaft of a probe stage and a drive shaft of a sample stage when matching of those two drive shafts is performed.

FIG. 9 illustrates the procedures for setting probe positions with intent to avoid damage of a probe tip.

### MODES FOR CARRYING OUT THE INVENTION

Embodiments of the present invention will be described in detail below with reference to the drawings. In the following description, devices having the same or similar functions are denoted by the same reference signs unless there is some particular reason.

### Embodiment 1

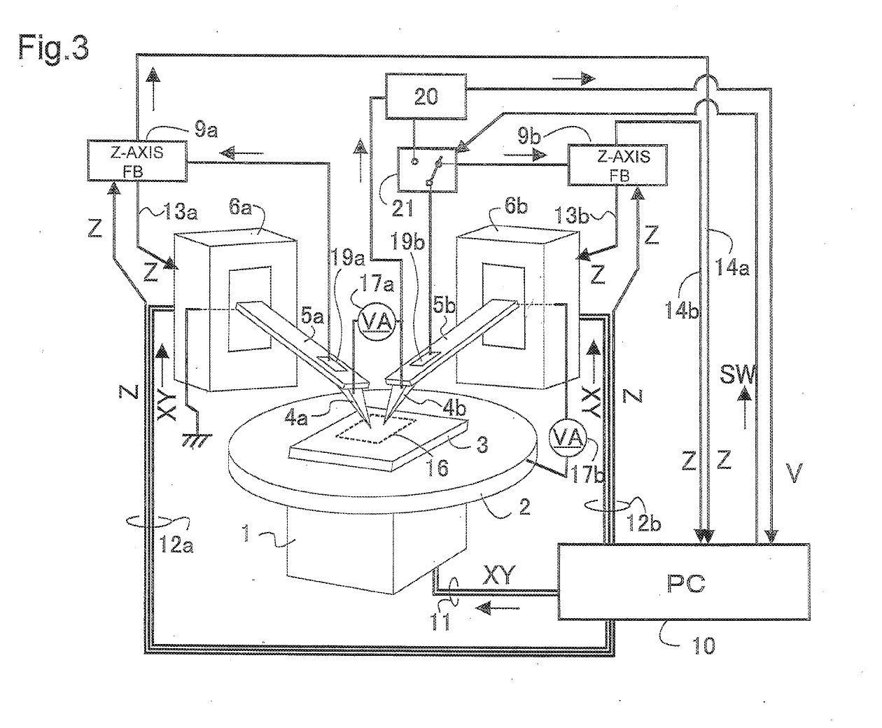

FIG. 3 is a schematic view of a scanning probe microscope prober using a self-sensing cantilever according to the present invention. It is generally known that there are several operation modes for an SPM, i.e., 1) a contact mode, 2) a noncontact mode, 3) a tapping mode, 4) a force mode, etc. The present invention can be applied to the SPM operating in any of the above modes. FIG. 3 illustrates, as a typical example, a multi-probe scanning probe microscope prober operating in the contact mode and using two AFMs.

A measurement object 3 is, e.g., a semiconductor chip for which a failure analysis is to be performed, and it is placed on a stage 2. The stage 2 is movable parallel to its surface, and is driven by a driver 1 along X- and Y-axes, which are defined in advance. For the measurement object 3, an AFM image is captured and electrical measurement is performed by employing a cantilever 5a (or 5b) that includes a probe 4a (or 4b). The cantilever 5a (or 5b) is movable by a cantilever driver 6a (or 6b) in predetermined X′-, Y′- and Z′-directions. In capturing the AFM image, the driver 1 scans an X′Y′-plane in accordance with an instruction from a computer 10. This scan may be a raster scan or a spiral scan.

The cantilever driver 6a (or 6b) is subjected to control by the computer 10 with respect to the X′Y′-plane, and to control by a feedback (FB) circuit 9a (or 9b) with respect to a Z′-axis. The control with respect to the Z′-axis is executed in a similar manner to that in an AFM using an ordinary self-sensing cantilever. In other words, an interatomic force is detected by sensing a flexure of a cantilever with the use of a sensor of, e.g., piezoelectric resistance detection, electrostatic capacitance detection, or piezoelectric detection, which is built in or attached to the cantilever. In FIG. 3, an interatomic force is detected, for example, as resistance change of a piezoelectric resistance 19a (or 19b) built in the cantilever, and feedback control is executed such that the detected interatomic force is held at a predetermined value. An example of cantilever is disclosed, together with a manufacturing method for the cantilever, in, e.g., patent Reference 5 (Japanese Unexamined Patent Application Publication No. 06-300557).

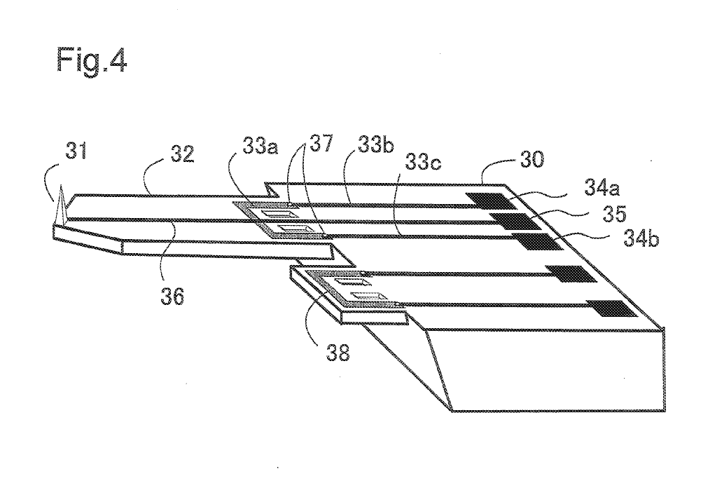

Each of the cantilevers 5a or 5b has a structure illustrated in FIG. 4. A cantilever 32 formed of a silicon substrate includes a probe 31 that is disposed at a tip of the cantilever 32 extending from a support 30. A wire 36 extends from the probe 31 toward the root of the cantilever 32 and reaches a lead-out electrode 35. A piezoelectric resistance 33a is formed by an impurity diffused layer that is disposed in the silicon substrate, and metal wires 33b and 33c are connected to the piezoelectric resistance 33a for supply of electric power through electrodes 34a and 34b. Although the impurity diffused layer and the metal wires are isolated by an insulating film, they are electrically connected to each other in parts through contact windows 37. A dummy resistance 38 for temperature compensation is disposed adjacent to the cantilever 32. The dummy resistance 38 is the same as the piezoelectric resistance 33a disposed in the cantilever.

Alternatively, a well-known bridge circuit may be constituted by preparing two other similar dummy resistances or equivalent two resistances in addition to the above-mentioned dummy resistance, i.e., three resistances in total, and by arranging those three resistances and the piezoelectric resistance, which is disposed in the above-mentioned cantilever, at positions corresponding to four sides of a quadrangular shape, respectively, and a flexure of the above-mentioned cantilever may be detected by sensing change of a resistance value of the piezoelectric resistance, which is disposed in the above-mentioned cantilever, with the use of the bridge circuit.

In the example illustrated in FIG. 3, a voltammeter 17a measures a voltage-current characteristic between the probes 4a and 4b. It is, however, apparent that a voltage-current characteristic between wires connected to those probes may be measured. Furthermore, a voltammeter 17b is arranged to measure a voltage-current characteristic between the wire in the cantilever 5a and the stage 2 that is electrically connected to the measurement object 3.

Here, the piezoelectric resistance 19b in the cantilever is exclusively connected to an output of a voltage follower 20 or an input of a Z-axis feedback (FB) controller 9b by a switch 21 that is controlled by the computer 10. The voltage follower 20 is a device for generating a voltage that is resulted from adding a predetermined offset voltage to a potential of the probe 4b, and a value of the offset voltage is usually zero. When the piezoelectric resistance 19b is connected to the output of the voltage follower 20 and when the offset voltage is zero, a leak current generated in the probe 4b or the wire connected to the probe 4b can be suppressed. Such suppression of the leak current is similar to the function of an ordinary guard electrode. Accurate measurement can be performed by measuring the voltage-current characteristic between the probes 4a and 4b in a state where the leak current is small as described above.

When the piezoelectric resistance 19b is connected to the input of the Z′-axis feedback (FB) controller 9b, the SPM prober can be operated as a well-known interatomic force microscope by scanning a scan region 16 while a weak force applied to the probe is held constant.

Accordingly, by changing over the switch 21 after obtaining an image with the interatomic force microscope, a position of the probe can be adjusted with the aid of the obtained image. As a result, electrical measurements can be performed in a state where the probe is accurately set up aiming at a microscopic measurement portion.

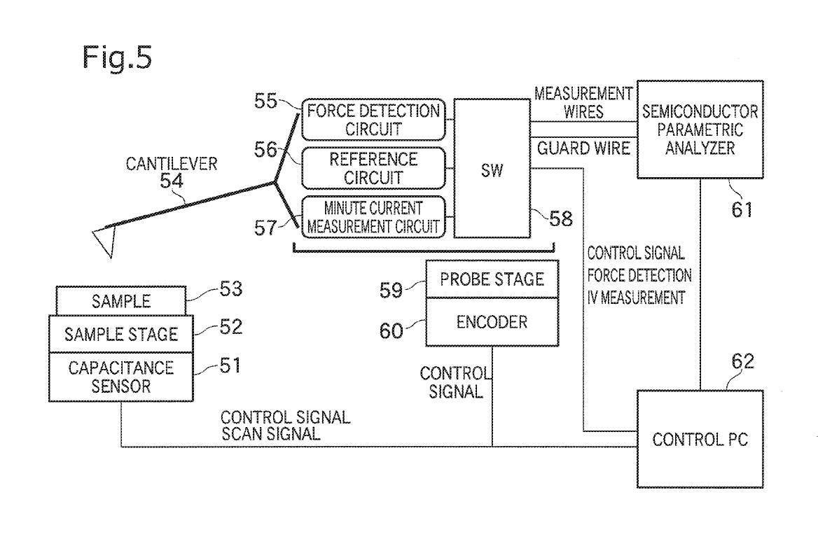

FIG. 5 is a block diagram of the scanning probe microscope prober using the self-sensing cantilever according to the present invention. In FIG. 5, a sample 53 is placed on a sample stage 52, and the sample stage 52 is controlled by a control PC 62. Creep is controlled in a closed loop using a capacitance sensor 51.

A force detection circuit 55 and a minute current measurement circuit 57, including a reference circuit 56, are provided with the cantilever 54. A force detecting function and a minute current measuring function are changed over by a switch (SW) 58 that is controlled by the control PC 62. In the illustrated example, the cantilever 54, the force detection circuit 55, the minute current measurement circuit 57, and the switch 58 are disposed on a probe stage 59. The probe stage 59 includes an encoder 60, and position information of the probe stage 59 is transferred to the control PC 62. The results of measuring a voltage and a current in the force detection circuit 55 and the minute current measurement circuit 57 are analyzed by a semiconductor parametric analyzer 61. The semiconductor parametric analyzer 61 is further able to maintain the potential of a guard wire. The semiconductor parametric analyzer 61 can be controlled by the control PC 62.

### Embodiment 2

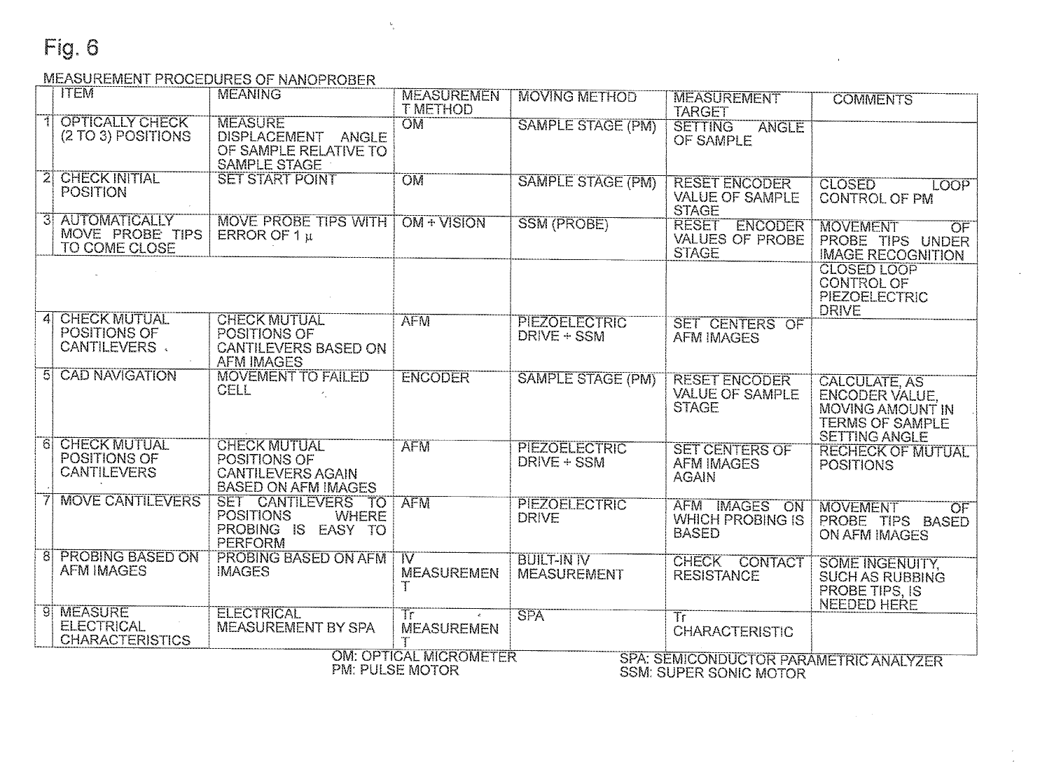

The electrical measurements of the measurement object 3 by the above-described scanning probe microscope prober using the self-sensing cantilever, illustrated in FIG. 3, are performed in accordance with the procedures illustrated in FIG. 6, for example.

1. Several positions are optically checked while the sample stage is moved. These checks are to measure a displacement angle of a sample relative to the sample stage depending on how the sample is placed on the sample stage.

2. An initial position is checked to set a start point. At this time, an encoder value of the sample stage is reset.

3. The probe stages are driven with the aid of an optical microscope image for automatically moving the probe tips to come close to each other. The movement of the probe tips in this case can be performed with an error of about 1 micron.

Here, closed loop control of the sample stage is started.

4. Mutual positions of the cantilever probes are checked. This check is performed with the aid of, e.g., AFM images.

5. The probes are moved to a failure location by driving the probe stages. When a failure analysis of a microscopic semiconductor device is performed, a moving direction and a moving distance of the stage can be preset by utilizing CAD data of the semiconductor device.

6. Mutual positions of the cantilever probes are rechecked. This recheck is performed with the aid of, e.g., the above-mentioned AFM images.

7. The probe tips of the cantilevers are moved. This movement of each probe tip is to set the cantilever at a position where the probe tip can be easily set up. For example, AFM images are used in moving the probe tips. If the above-mentioned AFM images are available depending on situations, those AFM images may be used.

8. The probe tips are set up to establish electrical contact, and predetermined voltage and current measurements are performed.

Alternatively, the electrical measurements may be performed as follows.

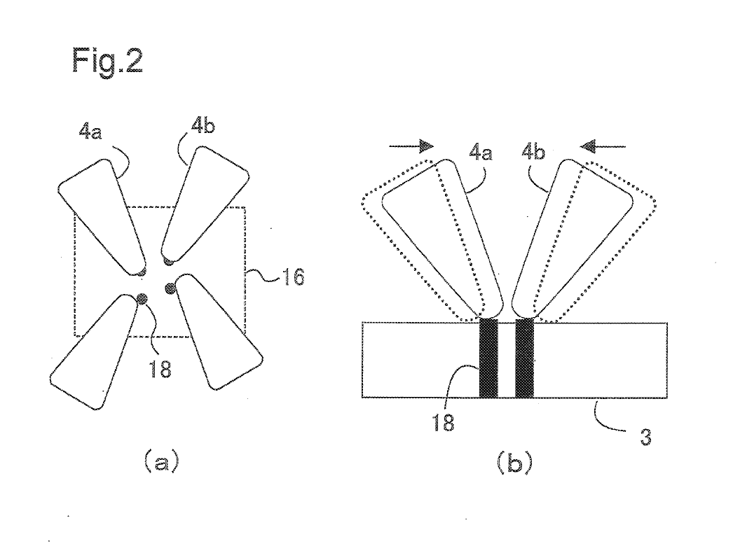

1) A plurality of probes are arranged at positions spaced apart from each other by a predetermined distance. At that time, the probes are arranged to fall within, e.g., the predetermined region 16 illustrated in FIG. 2(a). Such an arrangement can be easily realized by utilizing an alignment mark, or by capturing AFM images instead. When the scan region 16 has a comparatively large size, such an arrangement can also be realized by employing an optical microscope. Here, for the reason described later, the probes are desirably arranged as close as possible to each other.

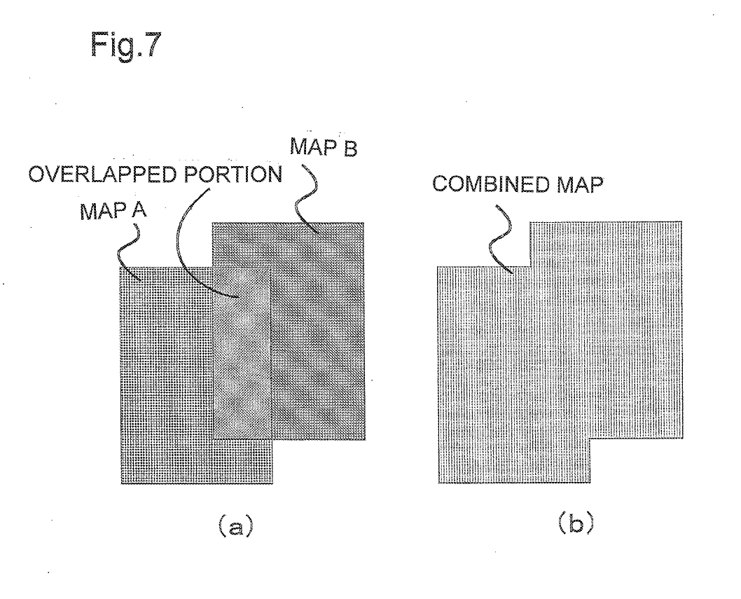

2) The movable stage 2 is raster-scanned by the probes, and AFM images including an overlapped region are obtained as images captured by the probes, respectively. It is apparent that sizes of raster-scanned regions are desirably as small as possible from the viewpoint of performing rapid measurement. However, the raster-scanned regions are needed to have such sizes allowing those regions to overlap with each other. For example, a map A and a map B illustrated in FIG. 7(a) are obtained, as AFM images, by employing the probes 4a and 4b, respectively. In the case of raster scan, because final scan positions of the probes 4a and 4b are located at respective corner of the maps A and B, the probes are desirably returned to near respective centers of the maps. A spiral scan directing toward the inner side from the outer side is desirable for the reason that the final scan position of each probe is located near the center of the scan region.

3) The above-mentioned overlapped region in the obtained images is found, and respective positions of the probes are read. The overlapped region is, for example, an overlapped portion illustrated in FIG. 7(a). Finding of the overlapped portion can be performed by evaluating correlation coefficients while relative positions of the maps A and B are changed a little by a little, and by finding a portion where the correlation coefficient is maximized. A combined map illustrated in FIG. 7(b) can be obtained by joining those two maps with each other at the overlapped portion. As a matter of course, the combined map covers a larger area than the scan region.

Subsequent to the above-described operation of the sample stage, each cantilever is driven by the probe stage, and the probe is set up at a point where the measurement is to be performed. At that time, a drive shaft of the probe stage and a drive shaft of the sample stage are often not matched with each other. Thus, the drive shaft of the probe stage and the drive shaft of the sample stage are matched with each other by comparing an image (e.g., an AFM image or an STM image) resulting from a scan of the probe stage and an image (e.g., an AFM image) resulting from a scan of the cantilever with driving of the sample stage.

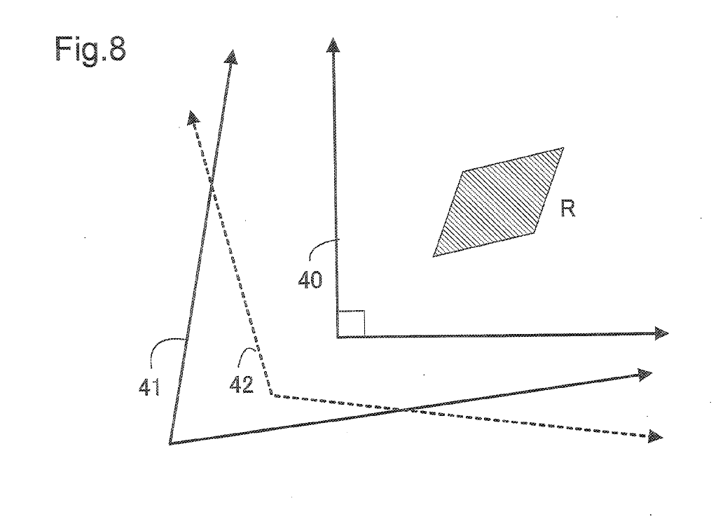

The above-described matching is equivalent to a process of, as illustrated in FIG. 8, regarding those drive shaft as coordinate axes, determining a conversion equation between a coordinate system 41 of the sample stage and a reference coordinate system 40, and determining a conversion equation between a coordinate system 42 of the probe stage and the reference coordinate system 40. On that occasion, it is apparent that any one of the coordinate systems 41 and 42 may be used as the reference coordinate system. Since a moving range with each of the above-mentioned drive systems is limited to a microscopic region, the above conversion equations give satisfactory accuracy as a liner equation.

In other words, the above-described matching is to, by comparing a two-dimensional distribution A obtained with driving of the sample stage for a predetermined position of the same measurement object and a two-dimensional distribution B obtained with driving of the probe stage for a predetermined position of the same measurement object, determine conversion coefficients of a linear conversion equation for coordinate values indicated by a linear encoder of the sample stage and conversion coefficients of a linear conversion equation for coordinate values indicated by a linear encoder of the probe stage in accordance with the well-known method.

Further, there is provided coordinate conversion means for executing coordinate conversion based on one of the coordinate systems of the sample stage and the probe stage, or a coordinate system different from those coordinate systems by employing the conversion coefficients for the purpose of driving the sample stage or the probe stage. In particular, an operation of moving the probe to the predetermined position in accordance with the above-mentioned two-dimensional distribution during the above-mentioned second period in which the above-mentioned sensor disposed on the cantilever is used as a guard electrode is performed by employing values for movement obtained through conversion with the above-mentioned coordinate conversion means.

4) The probes are moved to the respective predetermined positions. In this stage, the above-described combined map can be used.

5) The measurement object is measured. At this time, as illustrated in FIG. 2(b), the probes 4a and 4b are often displaced, for example, from dot-line images toward solid-line images. When electrical conduction is established by bringing the probe into pressure contact with, e.g., the conductive plug 18 that is buried in a contact hole or a through hole in the measurement object, it often happens that the probe slips over the surface of the measurement object and its position displaces. Thus, such a displacement is desirably taken into the distance necessary to establish the pressure contact.

### Embodiment 3

In above Embodiment, the probes are arranged at positions spaced apart from each other through the predetermined distance by employing an alignment mark or a substitute, or an optical microscope. In the case employing the optical microscope, even when the object has a relatively large size in comparison with the very fine wire, the probe tip is damaged in many cases if the object size is not greater than a limit recognizable by the optical microscope. In view of such a point, damage of the probe tip can be avoided in accordance with the following procedures.

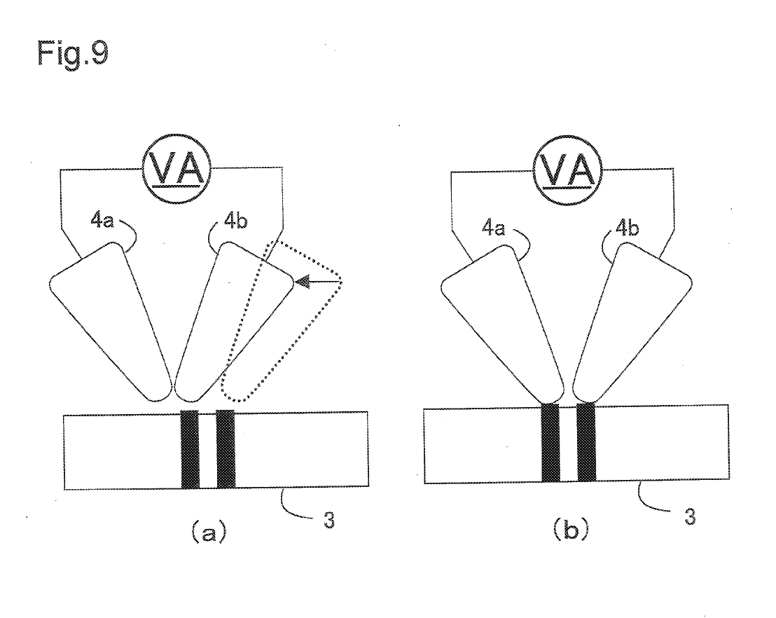

1) Respective positions of the probes are set such that conduction characteristics between the probes represent the probes being located at positions close to each other. For example, as illustrated in FIG. 9(a), one or both of the probes are moved to come into such a close state as generating flow of a tunnel current or an ion current with ionized gas. It is here important to stop the one or both probes with the aid of a voltammeter immediately before ordinary electrical conduction is established. The probes can also be set to the positions spaced apart from each other through a distance, which is substantially equal to that in the above-mentioned case, by making the probes approach each other through a distance therebetween to an extent that an interatomic force is developed.

On that occasion, if an excessive voltage is applied between the probes, the probes tend to contact with each other because they are attracted to come closer by the action of an electrostatic attractive force. Therefore, it is important that the voltage applied between the probes is set to a voltage value at a level to an extent that does not generate the obstructive electrostatic attractive force. The voltage is desirably applied through a high-resistance element. This can protect the probe tip from damage caused by an overcurrent. Furthermore, by employing a proper resistance value, an electric discharge by contact and an electric charge during the probes separate apart from each other are alternately occur, thus allowing the probe tip to vibrate. A state where the probes are close to each other can be detected by sensing such mechanical vibration or interruption of a current.

Moreover, by setting the probes to have the same voltage at a clearly positive or negative potential when looked from a potential in the surroundings, it is possible to generate an electrostatic repulsive force between the probes, and to make the probes come close to each other while holding the probes in a state under the action of the repulsive force.

In addition, the distance between the probes can be shortened in a manner of avoiding contact between the probes by applying an AC voltage at a frequency, which is higher than the natural vibration frequency of each probe, between the probes such that an attractive force and a repulsive force alternately act on the probes. The probes can be brought into a spaced apart state at positions very close to each other by reducing a mechanical pressure applied between the probes while the above-mentioned AC voltage is gradually reduced.

2) The probes are spaced from each other through a predetermined distance as illustrated in FIG. 9(b). The reason is that, if the probes are present at very close positions as described above, electrical measurements cannot be performed without causing interference between the probes. The predetermined distance in this stage is desirably as short as possible. This is intended to maximally increase a proportion of an area of the overlapped region between the above-described maps A and B when the areas of the scan regions are constant.

### INDUSTRIAL APPLICABILITY

The present invention can be readily applied to failure analyses of semiconductor devices, detailed analyses regarding a few failures caused at startup, and so on. Furthermore, the present invention can be effectively used in check of electrical characteristics under situations, such as represented by inline tests, where electrical contact is difficult to establish from the backside of a wafer when a failure analysis is performed in the wafer stage, for example.

### REFERENCE SIGNS LIST

1 driver
2 stage
3 measurement object
4a, 4b probes
5a, 5b cantilevers
6a, 6b cantilever drivers →probe stages
7a, 7b laser beam sources
8a, 8b 4-divided photodetectors
9a, 9b feedback (FB) circuits
10 computer
11 control line
12a, 12b control lines
13a, 13b signal lines
14a, 14b signal lines
15a, 15b laser beams
16 scan region
17a, 17b voltammeters
18 conductive plug
19a, 19b piezoelectric resistances
20 voltage follower
21 switch
30 support
31 probe
32 cantilever
33a piezoelectric resistance
33b, 33c metal wires
34a, 34b electrodes
35 lead-out electrode
36 wire
37 contact window
38 dummy resistance
40 coordinate system as reference
41 coordinate system of sample stage
42 coordinate system of probe stage
51 capacitance sensor
52 sample stage
53 sample
54 cantilever
55 force detection circuit
56 reference circuit
57 minute current measurement circuit
58 switch (SW)
59 probe stage
60 encoder
61 semiconductor parametric analyzer
62 control PC

1. A scanning probe microscope prober using a self-sensing cantilever capable of performing electrical measurements of a measurement object placed on a two-dimensionally scanned sample stage by employing a probe mounted on a two-dimensionally scanned probe stage, and capable of obtaining a two-dimensional distribution of a control variable used to hold a force acting on the probe or a current flowing through the probe at a predetermined value,
the prober comprising setting means for setting the probe to a position determined on basis of the two-dimensional distribution of the control variable, and measurement means for measuring a current or a voltage between the probe and a predetermined location of the measurement object,
wherein the probe is disposed at a distal end of a cantilever,
the cantilever is self-sensing cantilever,
the self-sensing cantilever includes a first wire through which the current is supplied to the probe, and a second wire used in a sensor circuit for detecting a deformation of the cantilever, and
the prober further comprises:
detection means for detecting change in an output of the sensor circuit;
guard potential generation means for causing the second wire to be employed as a guard wire for the first wire; and
second wire switching means for switching over the second wire to be used in a time division manner in one of a first period during which the second wire is used as a sensor, and a second period during which the second wire is held at a guard potential, and
wherein the probe moves, after obtaining the two-dimensional distribution in the first period, to a predetermined position on basis of the two-dimensional distribution in the second period to measure a current or a voltage of the first wire.

2. The scanning probe microscope prober using the self-sensing cantilever according to claim 1, wherein the two-dimensional distribution of the control variable is obtained by scanning the sample stage.

3. The scanning probe microscope prober using the self-sensing cantilever according to claim 1, wherein an operation of moving the probe to a predetermined position on basis of the two-dimensional distribution in the second period is performed by moving the probe stage.

4. The scanning probe microscope prober using the self-sensing cantilever according to claim 1,
wherein each of the sample stage and the probe stage includes a linear encoder for detecting displacements of the stage in three-dimensional directions, and a drive system for driving the stage in the three-dimensional directions,
the prober includes closed loop control systems each including the linear encoder and the drive system, and controlling the corresponding stage to be held at a predetermined position of the linear encoder, and
closed loop control is executed in at least one of the closed loop control systems in the second period.

5. The scanning probe microscope prober using the self-sensing cantilever according to claim 1, further comprising determination means for determining whether a voltage-current characteristic is within a predetermined range with respect to a measured value of the current or the voltage of the first wire,
wherein the measurement is performed through the steps of:
(1) determining the voltage-current characteristic by the determination means when the current or the voltage is measured,
(2) when the voltage-current characteristic is within the predetermined range, outputting the measured current or voltage, and
(3) when the voltage-current characteristic is not within the predetermined range, obtaining the two-dimensional distribution of the control variable again, moving the probe to a predetermined position on basis of the two-dimensional distribution obtained again by moving the probe stage, and thereafter returning to the first step (1) for measuring.

6. The scanning probe microscope prober using the self-sensing cantilever according to claim 1, further comprising coordinate conversion means for determining, for a predetermined position of an identical measurement object, conversion coefficients between coordinate values indicated by a linear encoder of the sample stage and coordinate values indicated by a linear encoder of the probe stage from comparison between a two-dimensional distribution A obtained with driving of the sample stage and a two-dimensional distribution B obtained with driving of the probe stage, and executing coordinate conversion by employing the conversion coefficients,
wherein an operation of moving the probe to the predetermined position on basis of the two-dimensional distribution in the second period is performed by employing values for movement obtained through conversion with the coordinate conversion means.

7. The scanning probe microscope prober using the self-sensing cantilever according to claim 2, wherein an operation of moving the probe to a predetermined position on basis of the two-dimensional distribution in the second period is performed by moving the probe stage.
